(19) United States
(12) Patent Application Publication
(10) Pub. No.: US 2015/0153405 A1
(43) Pub. Date: Jun. 4, 2015

(54) AUTOMATIC TESTING SYSTEM AND METHOD

(71) Applicant: Princeton Technology Corporation, New Taipei City (TW)

(72) Inventors: Yung-Yu WU, New Taipei City (TW); Huei-Huang CHEN, New Taipei City (TW)

(73) Assignee: Princeton Technology Corporation, New Taipei City (TW)

(21) Appl. No.: 14/096,501

(22) Filed: Dec. 4, 2013

(51) Int. Cl. G01R 31/28; G01R 31/3167

(52) U.S. Cl. CPC G01R 31/2834; G01R 31/3167

(57) ABSTRACT

The present invention discloses an automatic testing system. The automatic testing system includes a field programmable gate array (FPGA), a digital-to-analog converter (DAC), an analog-to-digital converter (ADC), and a processor. The FPGA is preprogrammed with a digital signal protocol for testing a DUT. The FPGA generates a digital testing signal in compliance with the digital signal protocol and transmits the digital testing signal to the DUT. The FPGA receives a digital signal output generated by the DUT, analyzes the digital output signal based on the digital signal protocol and obtains a digital test result. The DAC converter generates an analog testing signal to the DUT such that the DUT generates an analog signal output. The ADC measures the analog signal output and gets an analog test result. The processor receives the digital and analog test results and determines whether the functions of the DUT are correct or not.

### BACKGROUND OF THE INVENTION

1. Field of the Invention

The invention relates to an automatic testing system, and more particularly, to an automatic testing system applying Field Programmable Gate Array (FPGA) therein.

2. Description of the Related Art

FIG. 1 is a schematic diagram showing a conventional automatic testing system 10 with an analyzer 14 for testing a device under test (DUT) 15. The DUT 15 is an audio integrated circuit and the analyzer 14 is an audio analyzer. The automatic testing system 10 includes a power supply 11, a logic I/O circuit 12, a general-purpose interface bus (GPIB) 13, and a processor 16. The automatic testing system 10 can provide functions of supplying and measuring digital and analog signals. In the automatic testing system 10, the processor 16 is coupled to and controls the power supply 11, the logic I/O circuit 12 and the GPIB 13. The logic I/O circuit 12 can realize the functions of the function generator (i.e. the logic I/O circuit 12 can transmit digital signals to the DUT 15 for testing the functions of the DUT 15.). The GPIB 13 is used as an interface for the logic I/O circuit 12 to externally control the analyzer 14 and the DUT 15. The power supply 11 supplies power to the VDD pin of the DUT 15.

When the automatic testing system 10 performs digital signal tests, the logic I/O circuit 12 generates and transmits digital testing signals DIN to the DUT 15. The DUT 15 generates a digital signal output DOUT according to the digital testing signals DIN. The logic I/O circuit 12 receives and analyzes the digital signal output DOUT and generates a digital test result. Finally, the logic I/O circuit 12 decides whether the digital functions of the DUT 15 are correct or not according to the digital test result.

When the automatic testing system 10 performs the analog signal tests, the processor 16, through the GPIB 13, controls the analyzer 14 to generate an analog testing signal AIN or an audio testing signal to the DUT 15. The DUT 15 generates an analog signal output AOUT according to the analog testing signal AIN. The analyzer 14 performs the analog test according to the analog signal output AOUT. The processor 16 reads the analog test result of the analyzer 14 via the GPIB 13. Finally, the processor 16 performs the computations of the analog functions according to the analog test result and decides whether the analog functions of the DUT 15 are correct or not.

Because the automatic testing system 10 performs the analog test of the DUT 15 via the analyzer 14, the ground between the automatic testing system 10 and the analyzer 14 may induce noise interference. The noise interference problem would affect the analog test result and cause misjudgment to the analog functions of the DUT 15. The automatic testing system 10 and the analyzer 14 also have a ground balance problem. Therefore the automatic testing system 10 needs a solution for solving the above-mentioned grounding problem and also needs to shorten the fixed waiting period during test to achieve steady test results.

On the other hand, if the DUT 15 has to be tested with multiple test items, it is necessary to increase test productivity. Nonetheless, the test productivity will be limited owing to the specification of the GPIB 13. For example, the communication protocol of the GPIB 13 stipulates that the GPIB 13 can only control one analyzer at a time; or otherwise the GPIB 13 needs time to read instructions, so that the performance of the GPIB 13 is restrained by its transmission rate.

### BRIEF SUMMARY OF THE INVENTION

An embodiment of the present invention provides an automatic testing system. The automatic testing system comprises a field programmable gate array (FPGA), a digital-to-analog converter, an analog-to-digital converter and a processor. The FPGA is preprogrammed with a digital signal protocol for testing a device under test (DUT). The FPGA generates a digital testing signal in compliance with the digital signal protocol and transmits the digital testing signal to the DUT. The FPGA receives a digital signal output generated by the DUT in response to the digital testing signal. The FPGA analyzes the digital signal output based on the digital signal protocol and generates a digital test result. The digital-to-analog converter generates an analog testing signal such that the DUT generates an analog signal output in response to the analog testing signal. The analog-to-digital converter measures the analog signal output and gets an analog test result. The processor manipulates the FPGA and the digital-to-analog converter to respectively generate the digital testing signal and the analog testing signal, and receives the digital test results and the analog test results to determine whether the functions of the DUT are correct or not according to the test results.

An embodiment of the present invention provides an automatic testing method. The automatic testing method includes the steps of: providing a field programmable gate array (FPGA), which is preprogrammed with a digital signal protocol for testing a DUT; transmitting a digital testing signal generated by the FPGA in compliance with the digital signal protocol to the DUT; receiving, by the FPGA, a digital signal output which is generated by the DUT in response to the digital testing signal; analyzing, by the FPGA, the digital signal output based on digital signal protocol and generating a digital test result; generating and transmitting, by a digital-to-analog converter, an analog testing signal to the DUT; generating, by the DUT, an analog signal output according to the analog testing signal; receiving and measuring, by an analog-to-digital converter, the analog signal output to get an analog test result; and receiving, by a processor, the digital test results and analog test results and decides whether the functions of the DUT are correct or not according to the test results.

### BRIEF DESCRIPTION OF THE DRAWINGS

The invention can be more fully understood by reading the subsequent detailed description and examples with references made to the accompanying drawings, wherein:

FIG. 1 is a schematic diagram showing a conventional automatic testing system 10 collaborating with an analyzer 14 for testing a DUT 15.

FIG. 2 is a schematic diagram of an automatic testing system 20 for testing a DUT 27, according to an exemplary embodiment of the invention.

FIG. 3 shows the ground noise measured when the automatic testing system 10 shown in FIG. 1 tests 1000 pieces of audio integrated circuits (DUTs.

FIG. 4 shows the ground noise measured when the automatic testing system 20 shown in FIG. 2 tests 1000 pieces of audio integrated circuits (DUTs).

FIG. 5A is a schematic diagram showing the backbone of the system of using the automatic testing system 10 shown in FIG. 1 for automatic testing.

FIG. 5B is a schematic diagram showing the backbone of the system of using the automatic testing system 20 shown in FIG. 2 for automatic testing.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims

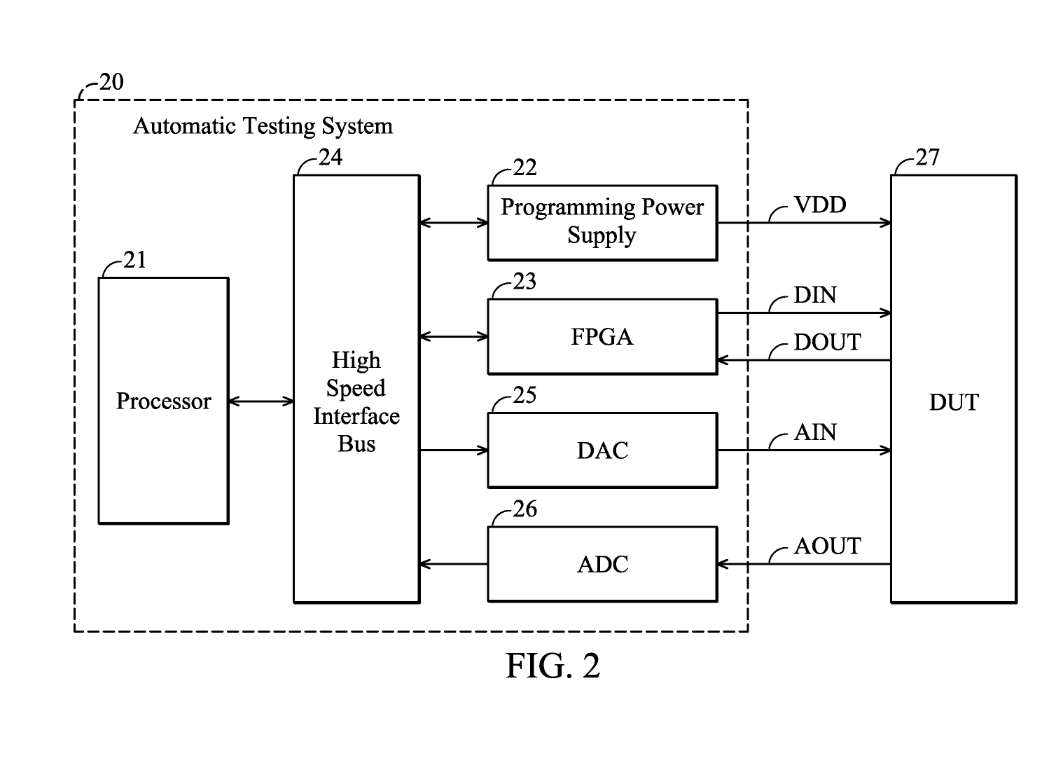

FIG. 2, shows an automatic testing system 20 according to an embodiment of the present invention. As the embodiment shown in FIG. 2, the automatic testing system 20 includes a processor 21, a programmable power supply 22, a Field Programmable Gate Array (FPGA) 23, a high-speed interface bus 24, a digital-to-analog converter (DAC) 25, and an analog-to-digital converter (ADC) 26.

In the embodiment of the present invention, the high speed interface bus 24 is a PXI (PCI eXtensions for Instrumentation) interface. As is well known in the art, the transmission efficiency of the PXI interface is a hundredfold of the general-purpose interface bus. Therefore, with the use of the PXI interface, the signal processing speed and the production efficiency of the automatic testing system can be improved during the test. The processor 21 is coupled to the PXI interface and controls the programmable power supply 22, the FPGA 23, the DAC and the ADC 26 through the PXI interface. The FPGA 23 is preprogrammed with a digital signal protocol for testing the device under test (DUT) 27, for example, an audio integrated circuit.

The processor 21 controls the programmable power supply 22, through a power supply pin VDD of the DUT 27 (not shown), to provide the DUT 27 with adjustable power for testing. It is noteworthy that the ground placements of the processor 21, the programmable power supply 22, the FPGA 23, the DAC 25 and the ADC 26 are configured with a single common ground.

When the automatic testing system 20 performs the digital signal tests, the processor 21 controls the FPGA 23 to generate a digital testing signal DIN in compliance with the digital signal protocol and transmit the digital testing signal DIN to the DUT 27 via the input/output (I/O) pin of the FPGA 23 (not shown). The DUT 27 generates a digital signal output DOUT in response to the digital testing signal DIN. After receiving the digital signal output DOUT, the FPGA 23 analyzes the digital signal output DOUT based on the digital signal protocol and thereby generating a digital test result. The processor 21, through the PXT interface, reads the digital test result and decides whether the digital functions of the DUT 27 are correct or not according to the digital test result.

When the automatic testing system 20 performs the analog signal tests, the processor 21, through the PXI interface, controls the DAC 25 to generate a specified analog testing signal AIN to the DUT 27. The DUT 27, based on its own configuration, generates an analog signal output AOUT in response to the analog testing signal AIN and transmits the analog signal output AOUT to the ADC 26. The analog signal output AOUT may be a gain signal or a harmonic signal. The ADC 26 measures the analog characteristics of the DUT 27 according to the analog signal output AOUT and obtains an analog test result. Finally, the processor 21 performs the computations of the analog functions according to the analog test result and decides whether the analog functions of the DUT 27 are correct or not.

Compared with the automatic testing system 10 described in the related art, the automatic testing system 20 of this embodiment can simultaneously perform the action of generating the analog testing signal AIN and the action of testing the analog characteristics of the DUT 27 according to the analog signal output AOUT and obtaining an analog test result. But in the related art, the analog function test of the DUT 15 is performed by the analyzer 14 which is located outside the automatic testing system 10, and the analyzer 14 cannot simultaneously perform the above-mentioned two actions. Therefore the automatic testing system 20 of this embodiment can reduce the time needed for testing.

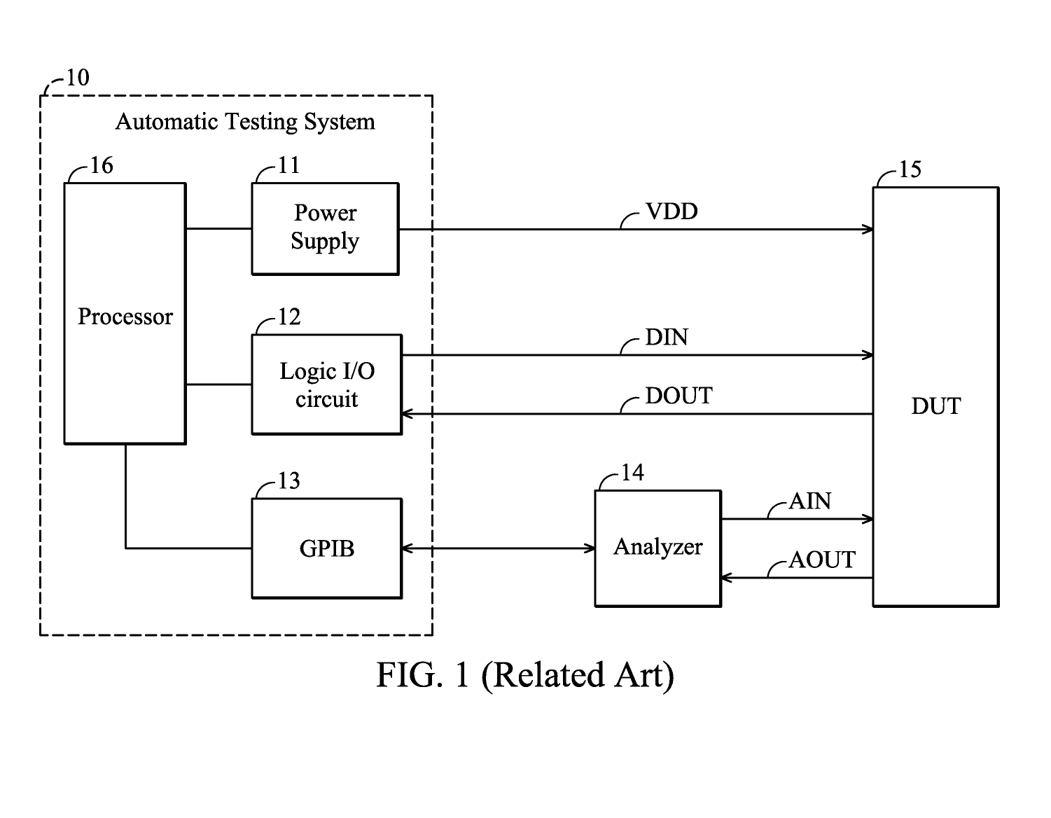

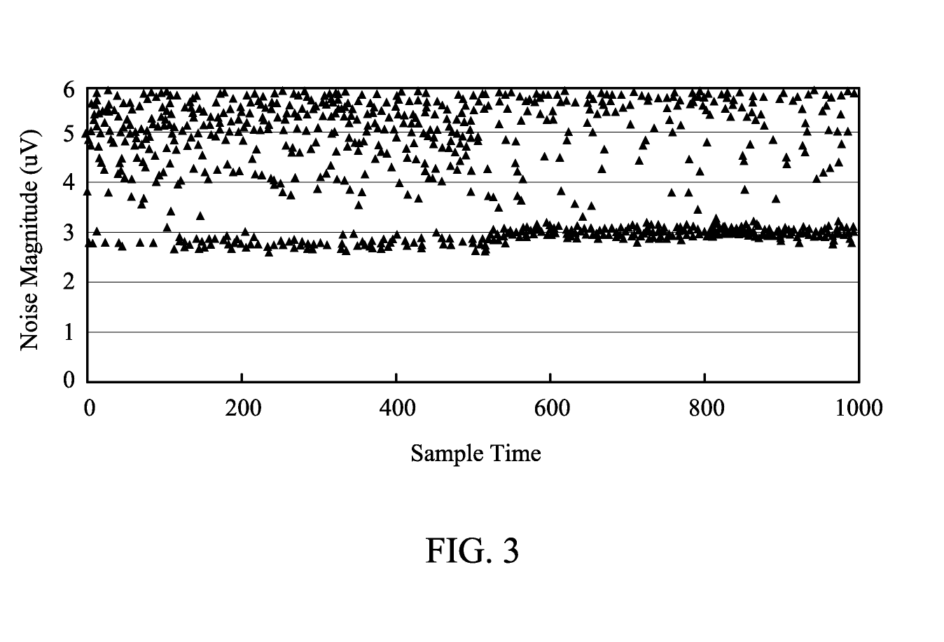

FIG. 3 shows the ground noise measured when the automatic testing system 10 shown in FIG. 1 tests 1000 pieces of audio integrated circuits (DUTs). In FIG. 3, the amplitudes of the ground noise with respect to the 1000 pieces of integrated circuits are scattered. Therefore it causes considerable bad influence for each audio integrated circuit test.

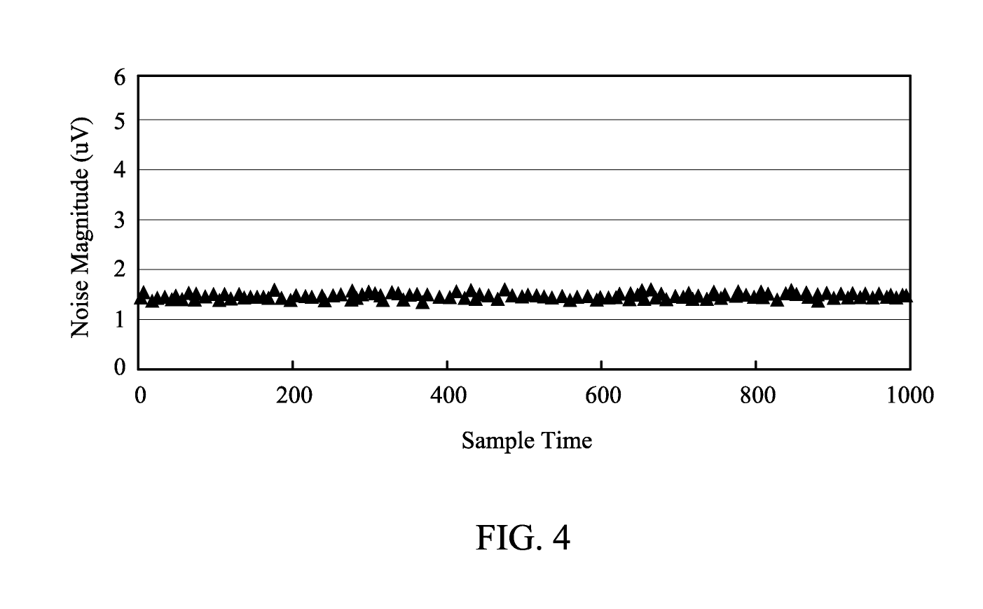

FIG. 4 shows the ground noise measured when the automatic testing system 20 shown in FIG. 2 tests 1000 pieces of audio integrated circuits (DUTs). In FIG. 4, the amplitudes of the ground noise with respect to the 1000 integrated circuits are very tidy. Therefore the automatic testing system 20 shown in FIG. 2 has the advantages of low ground noise and high stability. This is because the automatic testing system 20 and the DUT 27 shown in FIG. 2 are configured with a single common ground. Also, this indicates that the automatic testing system 20 shown in FIG. 2 is a high-accuracy automatic testing system. Therefore the automatic testing system 20 can avoid the noise interference induced during the mass production testing and significantly enhance the yield of the product.

In the related art, the automatic testing system 10, through the GPIB 13, controls only one analyzer 14 to measure the DUT 15. However the automatic testing system 20 of the present invention can simultaneously test a plurality of DUTs, and the number of DUT is decided by the respective number of pins of the FPGA 23, the DAC 25, the ADC 26, and the DUT 27. For example, suppose that the DUT 27 is an audio integrated circuit which has a power supply pin VDD, a set of I/O pins and four analog signal pins. If the automatic testing system 20 desires to simultaneously test two DUTs, the programmable power supply 22, the FPGA 23, the DAC 25, and the ADC 26 each requires two power supply pins VDD, two set of I/O pins, and eight analog signal pins. Thus, a person skilled in the art can set the number of pins of each device in the automatic test system 20 to determine the number of the audio integrated circuits that can be simultaneously tested. By simultaneously testing a plurality of DUTs, the automatic test system 20 of the present invention significantly enhances productivity.

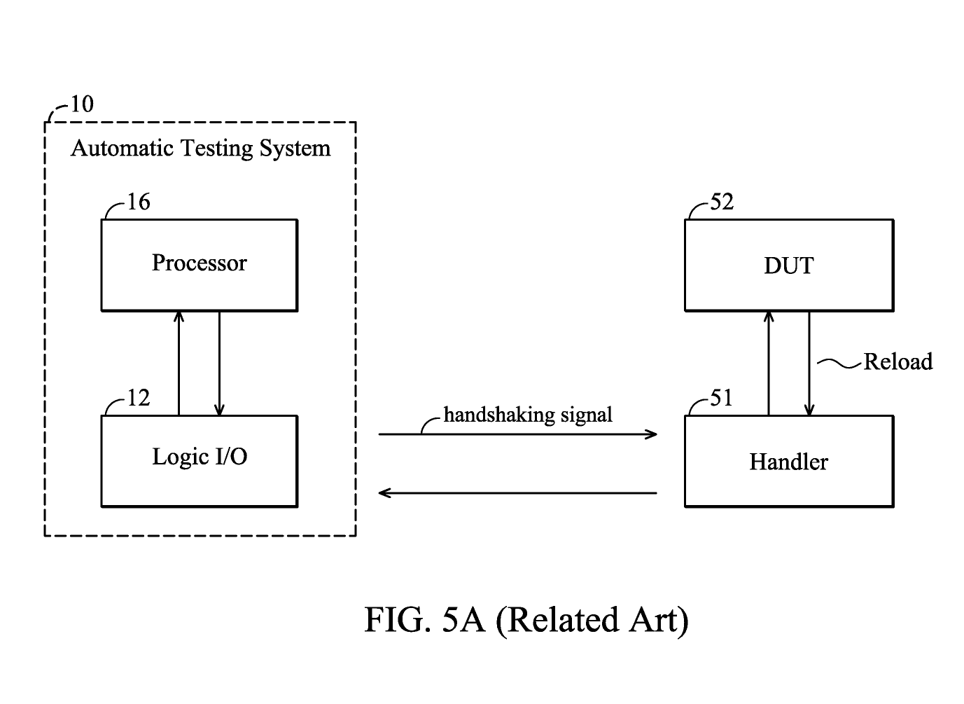

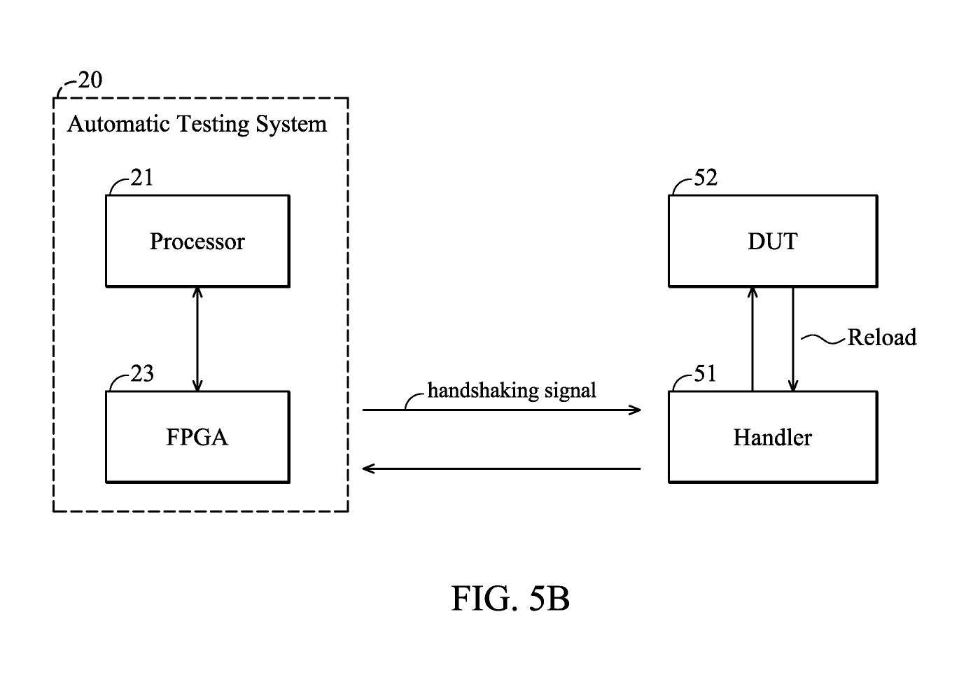

FIG. 5A is a schematic diagram showing the backbone of the system of using the automatic testing system 10 shown in FIG. 1 for automatic testing. As shown in FIG. 5(A), the logic I/O circuit 12 uses the internal I/O signal as a handshaking signal to execute the handshaking process with a handler 51. The process of the handshaking is manipulated by the processor 16. At this time, the logic I/O circuit 12 controls the handler 51 through the I/O signals to assign a DUT 52 to perform a specified operation (Reload) and thereby reaching the purpose of automatic testing.

FIG. 5B is a schematic diagram showing the backbone of the system of using the automatic testing system 20 shown in FIG. 2 for automatic testing. As an embodiment shown in FIG. 5B, the processor 21 only needs to inform the FPGA 23 to control the handler 51 to assign a DUT 52 to perform a specified operation (Reload), wherein the FPGA 23 is preprogrammed with the handshaking protocol which is used to execute the handshaking process with the handler 51. By using the FPGA 23 to share the work of the processor 21, the automatic testing system 20 improves the efficiency of production.

Similarly, without departing from the scope of the invention, a person skilled in the art can use the characteristics of the FPGA 23 to adjust the test demands of the automatic testing 20. For example, the FPGA 23 of the automatic testing system 20 can be preprogrammed with the digital signal protocol according to different test needs. Thus, the automatic testing system 20 can achieve real-time digital data comparison and discrimination. In addition, the present invention integrates the DAC 25 and the ADC 26 into the automatic testing system 20 such that the automatic testing system 20 can synchronize the digital testing operation and the analog testing operation, thereby reducing the waiting period needed for testing and the time wasted due to interruptions.

While the invention has been described by way of example and in terms of preferred embodiment, it is to be understood that the invention is not limited thereto. On the contrary, it is intended to cover various modifications and similar arrangements (as would be apparent to a person skilled in the art). Therefore, the scope of the appended claims should be accorded the broadest interpretation so as to encompass all such modifications and similar arrangements.

What is claimed is:

1. An automatic testing system, comprising:
a field programmable gate array (FPGA) preprogrammed with a digital signal protocol for testing a device under test (DUT) and configured to generate a digital testing signal in compliance with the digital signal protocol and transmit the digital testing signal to the DUT, receive a digital signal output generated by the DUT in response to the digital testing signal, and analyze the digital signal output based on the digital signal protocol and obtain a digital test result;
a digital-to-analog converter generates an analog testing signal to the DUT such that the DUT generates an analog signal output in response to the analog testing signal;
an analog-to-digital converter measures the analog signal output and obtains an analog test result; and
a processor receives the digital test result and the analog test result and determines whether functions of the DUT are correct or not according to the digital test result and the analog test result.

2. The automatic testing system of claim 1, further comprising a high-speed interface bus, wherein the processor is coupled to the high-speed interface bus and controls the FPGA, the digital-to-analog converter and the analog-to-digital converter via the high-speed interface bus.

3. The automatic testing system of claim 1, further comprising a programmable power supply, which provides the DUT with adjustable power for testing.

4. The automatic testing system of claim 1, wherein ground placements of the processor, the FPGA, the digital-to-analog converter, the analog-to-digital converter and the DUT are configured with a single common ground.

5. The automatic testing system of claim 1, wherein the DUT is an audio integrated circuit.

6. The automatic testing system of claim 1, wherein the FPGA is further preprogrammed with a handshaking protocol and configured to execute a handshaking process with a handler to assign the DUT to perform a specified operation.

7. An automatic testing method, comprising:
providing a field programmable gate array (FPGA), which is preprogrammed with a digital signal protocol for testing a device under test (DUT):
transmitting a digital testing signal generated by the FPGA in compliance with the digital signal protocol to the DUT;
receiving, by the FPGA, a digital signal output which is generated by the DUT in response to the digital testing signal;
analyzing, by the FPGA, the digital signal output based on the digital signal protocol and generating a digital test result;
generating and transmitting, by a digital-to-analog converter, an analog testing signal to the DUT;
generating, by the DUT, an analog signal output according to the analog testing signal;
receiving and measuring, by an analog-to-digital converter, the analog signal output to obtain an analog test result; and
receiving, by a processor, the digital test result and the analog test result and determining whether functions of the DUT are correct or not according to the digital test result and the analog test result.

8. The automatic testing method of claim 7, further comprising providing a high-speed interface bus for the processor to control the FPGA, the digital-to-analog converter, and the analog-to-digital converter.

9. The automatic testing method of claim 7, further comprising configuring ground placements of the processor, the FPGA, the digital-to-analog converter, the analog-to-digital converter, and the DUT with a single common ground.
